(19) United States
(12) Patent Application Publication
(10) Pub. No.: US 2008/0012816 A1
(43) Pub. Date: Jan. 17, 2008

(54) Shift register and display apparatus including the same

(76) Inventor: Seung-Hwan Moon, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/052,584

(22) Filed: Feb. 7, 2005

(30) Foreign Application Priority Data
Feb. 6, 2004 (KR) 10-2004-0007814

(51) Int. Cl. G09G 3/36; G11C 19/28

(52) U.S. Cl. 345/100; 345/204

(57) ABSTRACT

A shift register is provided, which includes: a plurality of stages sequentially outputting gate signals, each stage including: an input unit outputting a control signal based on an external signal; an output unit connected to the input unit and outputting a gate signal based on a first clock signal and the control signal; and a signal generating unit connected to the output unit and generating a transmission signal based on the first clock signal and the control signal.

### BACKGROUND OF THE INVENTION

(a) Field of the Invention

The present invention relates to a shift register and a display apparatus including the same.

(b) Description of Related Art

Recently, a liquid crystal display includes gate driving integrated circuits (ICs) mounted in a tape carrier package (TCP) type or a chip on glass (COG) type. However, the above-described structure has a limitation in manufacturing cost and apparatus design.

In order to overcome the limitation, a structure without gate driving ICs is suggested. This gives a shift register including amorphous silicon thin film transistors (TFTs) for generating scanning pulses the shift register, which can operate like the gate driving ICs.

FIG. 1 is a block diagram of a conventional shift register.

Referring to FIG. 1, the conventiona shift register outputting N gate signals (or scanning signals) GOUT₁, GOUT₂, . . . GOUT_{N} includes N stages.

A first stage receives a scan start signal STV and a first clock signal CKV from a signal controller (not shown) and outputs an output signal GOUT₁ for the first gate line. The output signal GOUT₁ is inputted into an input terminal IN of the second stage.

A second stage receives a second clock signal CKVB and the output signal GOUT₁ from the first stage and outputs an output signal GOUT₂ for the second gate line. The output signal GOUT₂ is inputted into an input terminal IN of the third stage.

In this way, an N-th stage receives the second clock signal CKVB and the output signal GOUT[N−1] from the (N−1)-th stage and outputs an output signal GOUT_{N} for the (N−1)-th gate line through an output terminal OUT.

FIG. 2 is a circuit diagram of the shift register shown in FIG. 1.

Referring to FIG. 2, each stage of the shift register includes a pull-up unit 110, a pull-down unit 120, a pull-up driving unit 130, and a pull-down driving unit 140, and outputs a gate signal (or a scanning signal) in response to the scan start signal STV or the output signal of a previous stage. For example, a first stage outputs a gate signal (or a scanning signal) in response to the scan start signal STV from the signal controller and remaining stages outputs a gate signal (or a scanning signal) in response to the output signal of a previous stage.

FIG. 3 shows waveforms of signals of the shift register shown in FIGS. 1 and 2.

Referring to FIGS. 2 and 3, the shift register receives one of the first clock signal CKV and the second clock signal CKVB having opposite phases by a unit of two horizontal periods and outputs the gate signals to the gate lines. At this time, the first and the second clock signals CKV and CKVB have amplitudes for driving the TFTs, for example, which swing about −8V to about 24V.

Referring to FIG. 2, the pull-down driving unit 140 maintains a node N1 in an off state during the operation of other stages after outputting the gate signals. The change of the characteristics of the TFTs due to the long off states and the failure of the TFT due to the temperature may deteriorate the display device.

### SUMMARY OF THE INVENTION

A shift register is provided, which includes: a plurality of stages sequentially outputting gate signals, each stage including: an input unit outputting a control signal based on an external signal; an output unit connected to the input unit and outputting a gate signal based on a first clock signal and the control signal; and a signal generating unit connected to the output unit and generating a transmission signal based on the first clock signal and the control signal.

The shift register may further include: a pull-up driving unit operating based on the first clock signal; and a pull-down driving unit connected to the input unit, the pull-up driving unit, and the output unit and operating based on the first clock signal, a second clock signal, the external signal, and a gate signal of a next stage.

The transmission signal may be a carry signal.

The first and second clock signals of adjacent stages may be reversed.

The first clock signal and the second clock signal may have opposite phases.

The input unit may include a first NMOS transistor having a drain and a gate connected to each other and receiving an external signal.

The output unit may include a second NMOS transistor having a drain receiving the first clock signal, a gate connected to a source of the first NMOS transistor, and a source connected to the gate through a first capacitor.

The signal generating unit may include a third NMOS transistor having a drain receiving the first clock signal CKV, a gate connected to the output unit, and a source connected to the gate through a second capacitor.

The pull-up driving unit may include: a fourth NMOS transistor including a gate and a drain commonly connected to receive the first clock signal and a source connected to the pull-down driving unit; and a fifth NMOS transistor including a drain receiving the first clock signal and a gate and a source connected to the pull-down driving unit.

The pull-down driving unit may include: sixth to eighth NMOS transistors conned in series between the external signal and and a low level voltage; ninth to tenth NMOS connected in parallel between the output of the input unit and the low level voltage; eleventh and twelfth NMOS transistors connected between the output of the fourth and fifth transistors and the low level voltage, respectively; and thirteenth and fourteenth NMOS transistors connected between the output of the output unit and the low level voltage. The second and eighth transistors have gates supplied with the second clock signal, the seventh transistor has a gate supplied with the first clock signal, a node between the sixth and the seventh transistors is connected to the output of the input unit, and a mode between the seventh and the eighth transistors is connected to the output of the output unit 540. The ninth and tenth transistors have gates supplied with a gate signal of a dummy stage and a gate signal of P next stage, respectively. The eleventh and twelfth transistors have gates commonly connected to the output of the output unit, the thirteenth transistor has a gate connected to the output of the fifth transistor, and the fourteenth transistor has a gate supplied with a gate signal of a next stage.

A display device displaying image data from an external device, the device is provided, which includes: a display panel including gate lines, data lines, display elements, and switching elements; a signal controller outputting image data, gate control signals, and data control signals; a shift register sequentially outputting gate signals to the gate lines in response to the gate control signals; and a data driving circuit outputting data signals to the data lines in response to the data control signals, wherein the shift register comprises a plurality of stages, each stage corresponding to a gate line, outputting a gate signal to the gate line, and outputting a transmission signal independent of the gate signal, and the shift register generates the gate signals based on a first clock signal, a second clock signal, a transmission signal of an adjacent stage, and a gate signal of a next stage.

The shift register may be formed on the display panel.

The gate control signals may be transmitted through wires formed on the display panel, wherein the first clock signal and the second clock signal may have opposite phases.

The transmission signal may be a carry signal.

### BRIEF DESCRIPTION OF THE DRAWINGS

The present invention will become more apparent by describing embodiments thereof in detail with reference to the accompanying drawings in which:

FIG. 1 is a block diagram of a conventional shift register.

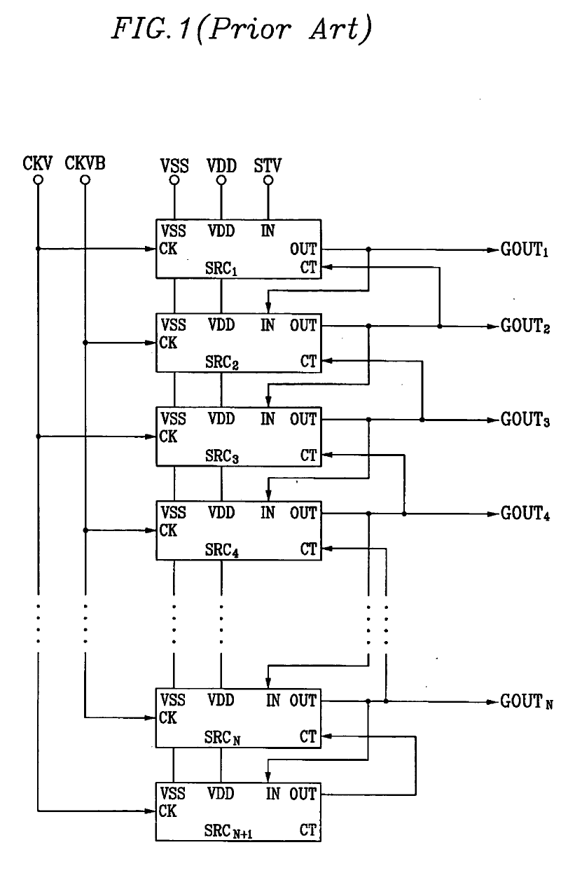

FIG. 2 is a circuit diagram of the shift register shown in FIG. 1.

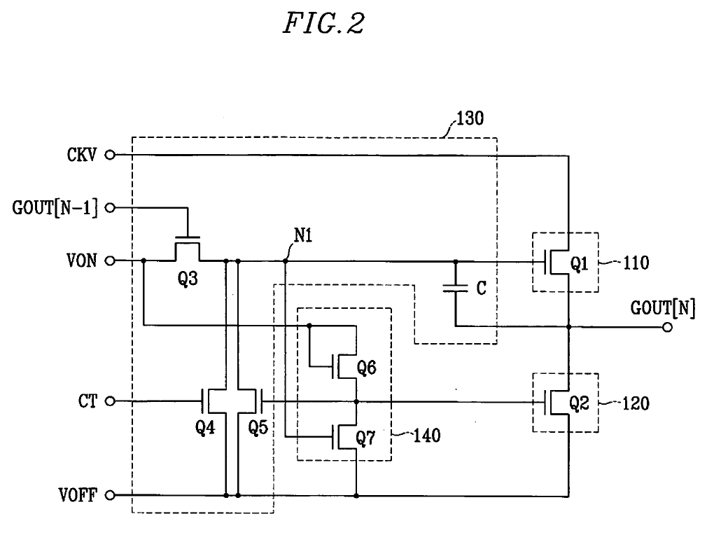

FIG. 3 shows waveforms of signals of the shift register shown in FIGS. 1 and 2.

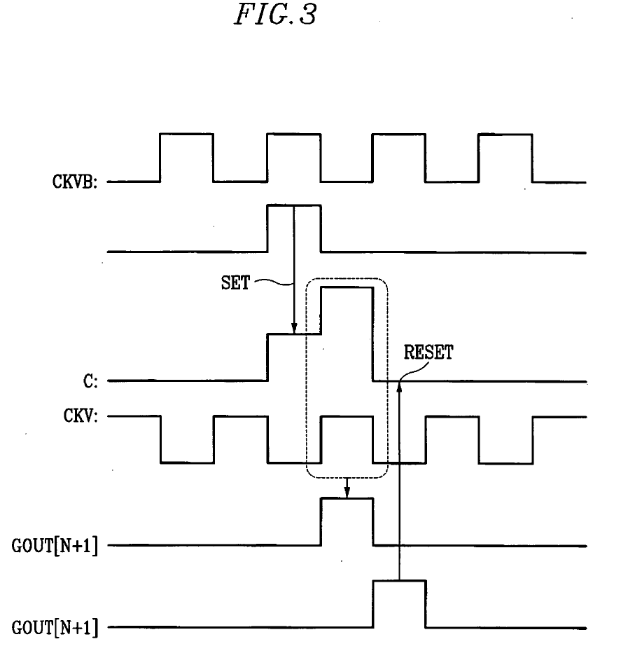

FIG. 4 is a schematic diagram of a display device according to an embodiment of the present invention.

FIG. 5 is a block diagram of a shift register according to a first embodiment of the present invention.

FIG. 6 is a block diagram of a shift register according to a second embodiment of the present invention.

FIG. 7 is a circuit diagram of a stage of the shift register shown in FIG. 6; and

FIG. 8 illustrates waveforms of outputs of the shift register shown in FIGS. 6 and 7.

### DETAILED DESCRIPTION OF THE PREFERRED EMBODIMENTS

The present invention now will be described more fully hereinafter with reference to the accompanying drawings, in which preferred embodiments of the invention are shown. The present invention may, however, be embodied in many different forms and should not be construed as limited to the embodiments set forth herein.

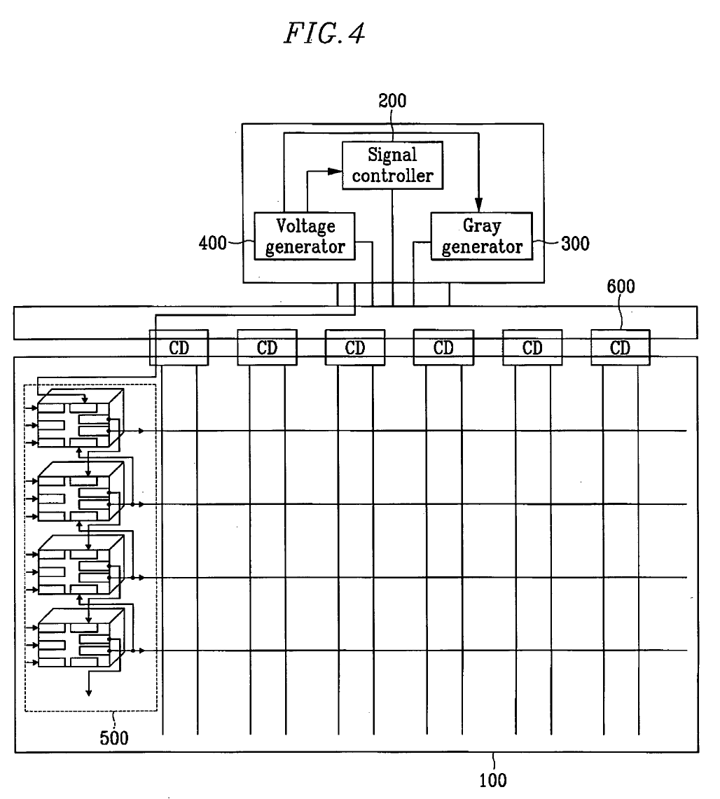

FIG. 4 is a schematic diagram of a display device according to an embodiment of the present invention.

Referring to FIG. 4, a display device according to this embodiment includes a display panel 100, a signal controller 200, a gray generator 300, a voltage generator 400, a shift register 500, and a data driving circuit 600.

The signal controller 200 receives digital image data and control signals from an external device, generates several control signals for controlling the shift register 500 and the data driving circuit 600, and supplies the digital image data to the data driving circuit 600 in accordance with the control signals. The control signals from signal controller 200 to the shift register 500 are supplied through a FPC (flexible printed cable) or a TCP and through wires on the display panel. In detail, the control signals are supplied to the first stage of the shift register 500 through a FPC or a TCP mounting the data driving circuit 600 and through wires on the display panel.

The data driving circuit 600 converts the digital image data supplied from the signal controller 200 into analog voltages in accordance with the control signals and supplies the voltages to a plurality of data lines formed on the display panel.

The shift register 500 generates driving pulses for controlling a plurality of data lines formed on the display panel. Referring to FIG. 4, the shift register 500 is formed on the display panel 100, and it operates in response to two clock signals, i.e., first and second clock signals having opposite phases and supplied from an external device.

The voltage generator 400 supplies voltages for the signal controller 200, the gray generator 300, the shift register 500, and the data driving circuit 600. For example, the voltage generator 400 generates a digital supply voltage DVdd, an analog supply voltage AVdd, and a gate on/off voltage Von/Voff.

The display panel 100 includes gate lines, data lines, display elements, and switching elements for controlling the display elements. The gray generator 300 generates reference voltages for color display based on the analog voltage supplied from an external device.

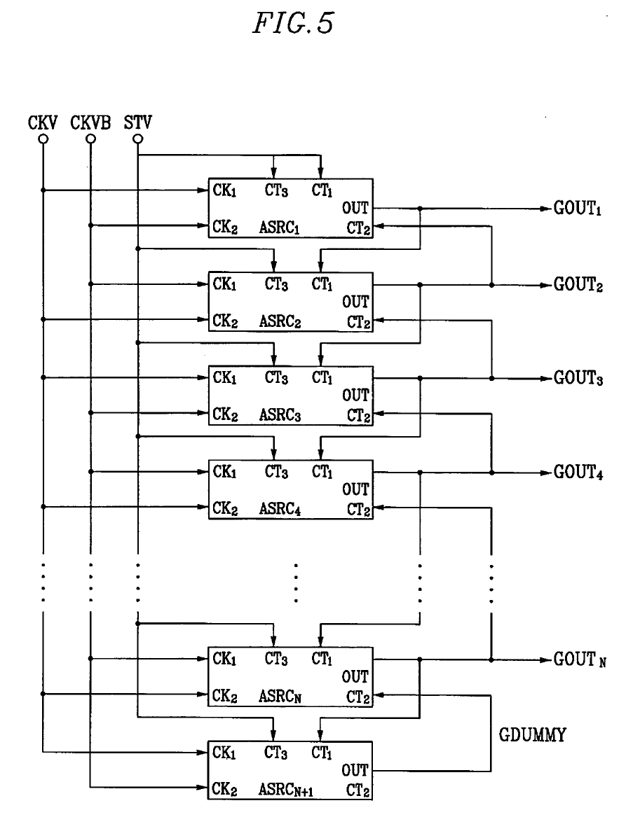

FIG. 5 is a block diagram of a shift register according to a first embodiment of the present invention.

Referring to FIG. 5, the shift register 500 includes N stages ASRC1, ASRC2, ASRC3, . . . , ASRCN outputting N gate signals GOUT₁, GOUT₂, . . . GOUT_{N} and a dummy stage ASRCN+1 outputting a gate signal GDUMMY. The shift register 500 is formed on a display panel (not shown) including switching elements (not shown) provided in areas defined by gate lines (not shown) and data lines (not shown).

The first stage ASRC1 of the shift register 500 receives first and second clock signals CKV and CKVB through first and second clock terminals CK1 and CK2, the scan start signal STV through first and third control terminals CT1 and CT3, and a gate signal GOUT₂ from a second stage ASRC2 through a second control terminal CT2. The first stage ASRC1 outputs a gate signal GOUT, to a first gate line and a first control terminal CT1 of the second stage ASRC2 through an output terminal OUT.

The second stage ASRC2 receives first and second clock signals CKV and CKVB through first and second clock terminals CK1 and CK2, the gate signal GOUT₁ of the first stage ASRC1 through a first control terminal CT1, a gate signal GOUT₃ from a third stage ASRC3 through a second control terminal CT2, and the scan start signal STV through a third control signal CT3. The second stage ASRC2 outputs a gate signal GOUT₂ to a second gate line and a first control terminal CT1 of the third stage ASRC3 through an output terminal OUT.

In this way, an N-th stage ASRCN receives first and second clock signals CKV and CKVB through first and second clock terminals CK1 and CK2, the gate signal GOUT_{N-1} of the (n−1)-th stage ASRCN−1 through a first control terminal CT1, a gate signal GOUT_{N+1} from the dummay stage ASRCN+1 through a second control terminal CT2, and the scan start signal STV through a third control signal CT3. The N-th stage ASRCN outputs a gate signal GOUT_{N} to a N-th gate line and a first control terminal CT1 of the dummay stage ASRCN+1 through an output terminal OUT.

The first and second clock signals CKV and CKVB are alternately supplied to the first and second clock terminals CK1 and CK2 of the stages of the shift register 500. In detail, the first stage ASRC1 is supplied with the first clock signal CKV through the first clock terminal CK1 and supplied with the second clock signal CKVB through the second clock terminal CK2. As for the second stage ASRC2, the first clock terminal CK1 is supplied with the second clock signal CKVB, while the second clock terminal CK2 is supplied with the first clock signal CKV.

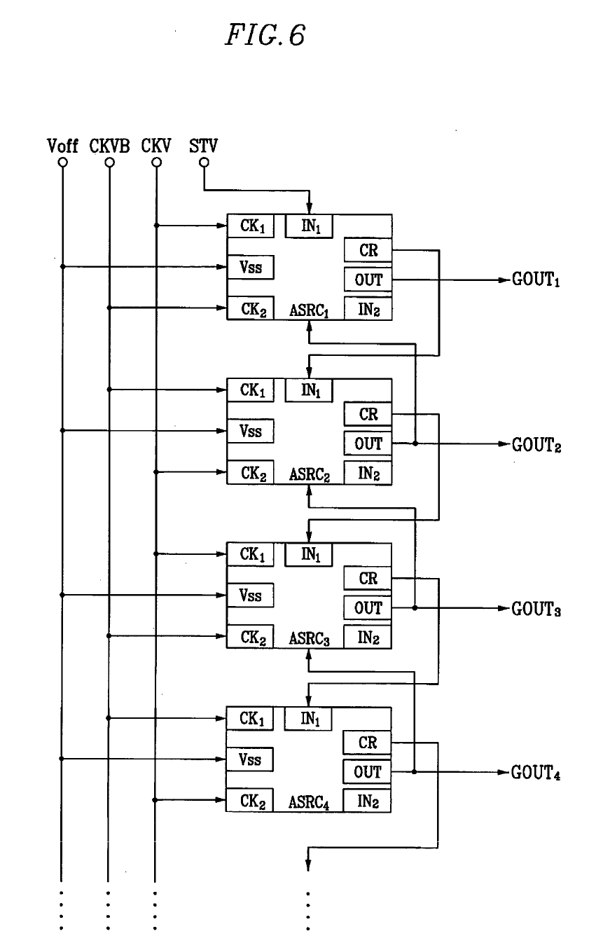

FIG. 6 is a block diagram of a shift register according to a second embodiment of the present invention.

Referring to FIG. 6, the shift register 500 the shift register 500 includes N stages ASRC1, ASRC2, ASRC3, . . . , ASRCN outputting N gate signals GOUT₁, GOUT₂, . . . GOUT_{N} and a dummy stage (not shown) outputting a gate signal GDUMMY. The shift register 500 is formed on a display panel 100 like the first embodiment.

The first stage ASRC1 of the shift register 500 receives first and second clock signals CKV and CKVB through first and second clock terminals CK1 and CK2, respectively, the scan start signal STV, and a gate signal GOUT₂ from a second stage ASRC2. The first stage ASRC1 outputs a gate signal GOUT₁ to a first gate line through an output terminal OUT and outputs a carry signal through a carry terminal CR based on the first clock signal CKV.

The second stage ASRC2 receives first and second clock signals CKV and CKVB through second and first clock terminals CK2 and CK1, respectively, the carry signal of the first stage ASRC1, and a gate signal GOUT₃ from a third stage ASRC3. The second stage ASRC2 outputs a gate signal GOUT₂ to a second gate line through an output terminal OUT and outputs a carry signal through a carry terminal CR based on the second clock signal CKVB.

In this way, an N-th stage ASRCN receives first and second clock signals CKV and CKVB through first or second clock terminal CK1 or CK2, a carry signal of the (n−1)-th stage ASRCN−1, and a gate signal GOUT_{N+}1 of the dummay stage through a second control terminal CT2. The N-th stage ASRCN outputs a gate signal GOUT_{N} to a N-th gate line through an output terminal OUT.

The first and second clock signals CKV and CKVB are alternately supplied to the first and the second clock terminals CK1 and CK2. Although each stage receives output signals of the nearest stages, i.e., the right previous stage and the right next stage, it may receive output signals of other stages such as next nearest stages or other next stages. For example, the N-th stage may receive gate signals from the stages farther than the (N+2)-th or the (N−2)-th stage.

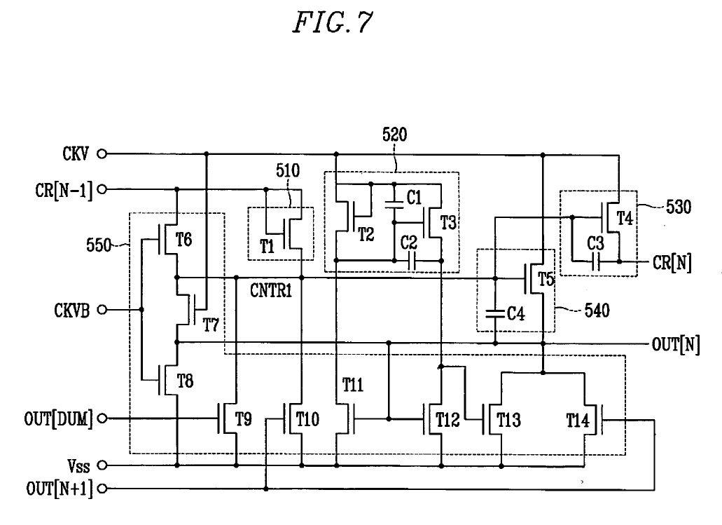

FIG. 7 is a circuit diagram of a stage of the shift register shown in FIG. 6.

Referring to FIG. 7, each stage of the shift register includes the input unit 510, the pull-up driving unit 520, the signal generating unit 530, the output unit 540, and the pull-down driving unit 550. The figure shows an N-th stage.

The input unit 510 includes an NMOS transistor T1 having a drain and a gate connected to each other and receiving a carry signal CR[N−1] from a previous stage, i.e., the (N−1)-th stage. The input unit outputs a first control signal CNTR1 through a source based on the carry signal CR[N−1].

The pull-up driving unit 520 includes a pair of transistors T2 and T3 receiving the first clock signal CKV through drain and outputting it through source. The transistor T2 has a gate connected to the source, the transistor T3 has a gate connected to the drain and the source through first and second capacitors C1 and C2, respectively.

The signal generating unit 530 includes an NMOS transistor T4 having a drain receiving the first clock signal CKV, a gate connected to the output CNTR1 of the input unit 510, and a source connected to the gate through a third capacitor C3. The signal generating unit 530 outputs a carry signal CR[N] based on the first control signal CNTR1 and the first clock signal CKV.

The output unit 540 includes an NMOS transistor T5 having a drain receiving the first clock signal CKV, a gate connected to the output CNTR1 of the input unit 510, and a source connected to the gate through a fourth capacitor C3. The output unit 540 outputs a gate signal OUT[N] based on the first control signal CNTR1 and the first clock signal CKV.

The pull-down driving unit 550 includes three NMOS transistors T6-T8 conned in series between a carry signal CR[N−1] of an (N−1)-th stage and a low level voltage Vss, a pair of NMOS transistors T9 and T10 connected in parallel between the output CNTR1 of the input unit 510 and the low level voltage Vss, a pair of NMOS transistors T11 and T12 connected between the output of the transistors T2 and T3 of the pull-up driving unit 520 and the low level voltage Vss, respectively, and a pair of NMOS transistors T13 and T14 connected between the output of the output unit 540 and the low level voltage Vss.

The transistors T6 and T8 have gates supplied with the second clock signal CKVB, and the transistor T7 has a gate supplied with the first clock signal CKV. A node between the transistor T6 and the transistor T7 is connected to the output CNTR1 of the input unit 510, and a mode between the transistor T7 and the transistor T8 is connected to the output OUT[N] of the output unit 540.

The transistors T9 and T10 have gates supplied with a gate signal OUT[DUM] of the dummy stage and a gate signal OUT[N+1] of the (N+1)-th stage, respectively, and the transistors T11 and T12 have gates commonly connected to the output OUT[N] of the output unit 540.

The transistor T13 has a gate connected to the output of the transistor T3 of the pull-up driving unit 520, and the transistor T14 has a gate supplied with the gate signal OUT[N+1] of the (N+1)-th stage.

As described above, each stage of the shift register 500 is supplied with both the first and second clock signals CKV and CKVB, and the first and second clock signals CKV and CKVB are alternately supplied with two terminals of the stages.

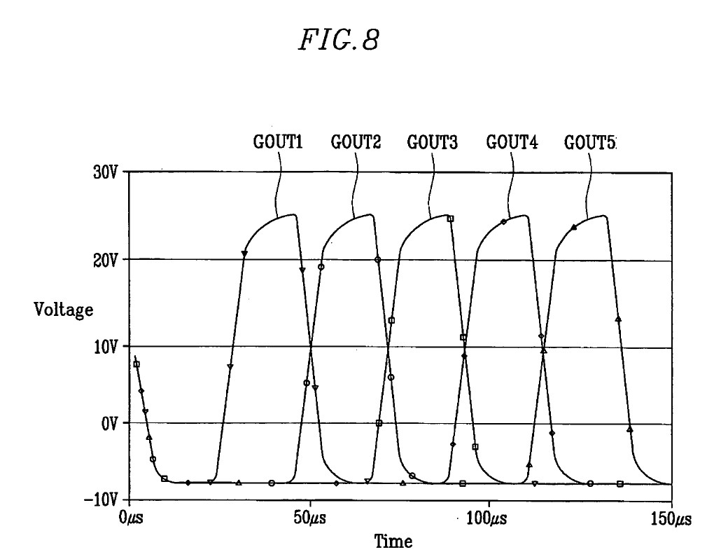

FIG. 8 illustrates waveforms of outputs of the shift register shown in FIGS. 6 and 7.

Referring to FIG. 8, the gate signals GOUT1, GOUT2, GOUT3, . . . from each stage of the shift register 500 have the same gradient and have a waveform that is almost rectangular, and they have a voltage level of about 25V.

As shown in FIG. 8, the signal generating unit 530 of each stage can normally operate the shift register although the threshold voltage of amorphous silicon TFTs is changed due to the temperature change, etc.

The shift register can be applied to various display devices such as an LCD and an organic light emitting display.

To summarize, each stage of the shift register is supplied with both the first clock signal CKV and the second clock signal CKVB, and the signal generating unit for generating the carry signal. Accordingly, the shift register can be insensitive to the threshold voltage of the TFTs. That is, the failure of the shift register due to the deviation of the threshold voltages of the TFTs a-Si can be prevented, thereby increasing the reliability of the shift register.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A shift register comprising:
a plurality of stages sequentially outputting gate signals, each stage including:
an input unit outputting a control signal based on an external signal;
an output unit connected to the input unit and outputting a gate signal based on a first clock signal and the control signal; and
a signal generating unit connected to the output unit and generating a transmission signal based on the first clock signal and the control signal.

2. The shift register of claim 1, further comprising:
a pull-up driving unit operating based on the first clock signal; and
a pull-down driving unit connected to the input unit, the pull-up driving unit, and the output unit and operating based on the first clock signal, a second clock signal, the external signal, and a gate signal of a next stage.

3. The shift register of claim 2, wherein the transmission signal is a carry signal.

4. The shift register of claim 2, wherein the first and second clock signals of adjacent stages are reversed.

5. The shift register of claim 4, wherein the first clock signal and the second clock signal have opposite phases.

6. The shift register of claim 2, wherein the input unit comprises a first NMOS transistor having a drain and a gate connected to each other and receiving an external signal.

7. The shift register of claim 6, wherein the output unit comprises a second NMOS transistor having a drain receiving the first clock signal, a gate connected to a source of the first NMOS transistor, and a source connected to the gate through a first capacitor.

8. The shift register of claim 7, wherein the signal generating unit comprises a third NMOS transistor having a drain receiving the first clock signal CKV, a gate connected to the output unit, and a source connected to the gate through a second capacitor.

9. The shift register of claim 8, wherein the pull-up driving unit comprises:
a fourth NMOS transistor including a gate and a drain commonly connected to receive the first clock signal and a source connected to the pull-down driving unit; and
a fifth NMOS transistor including a drain receiving the first clock signal and a gate and a source connected to the pull-down driving unit.

10. The shift register of claim 9, wherein the pull-down driving unit comprises:
sixth to eighth NMOS transistors conned in series between the external signal and and a low level voltage;
ninth to tenth NMOS connected in parallel between the output of the input unit and the low level voltage;
eleventh and twelfth NMOS transistors connected between the output of the fourth and fifth transistors and the low level voltage, respectively; and
thirteenth and fourteenth NMOS transistors connected between the output of the output unit and the low level voltage,
the second and eighth transistors have gates supplied with the second clock signal, the seventh transistor has a gate supplied with the first clock signal, a node between the sixth and the seventh transistors is connected to the output of the input unit, and a mode between the seventh and the eighth transistors is connected to the output of the output unit 540,
the ninth and tenth transistors have gates supplied with a gate signal of a dummy stage and a gate signal of a next stage, respectively,
the eleventh and twelfth transistors have gates commonly connected to the output of the output unit,
the thirteenth transistor has a gate connected to the output of the fifth transistor, and
the fourteenth transistor has a gate supplied with a gate signal of a next stage.

11. A display device displaying image data from an external device, the device comprising:
a display panel including gate lines, data lines, display elements, and switching elements;
a signal controller outputting image data, gate control signals, and data control signals;
a shift register sequentially outputting gate signals to the gate lines in response to the gate control signals; and
a data driving circuit outputting data signals to the data lines in response to the data control signals,
wherein the shift register comprises a plurality of stages, each stage corresponding to a gate line, outputting a gate signal to the gate line, and outputting a transmission signal independent of the gate signal, and the shift register generates the gate signals based on a first clock signal, a second clock signal, a transmission signal of an adjacent stage, and a gate signal of a next stage.

12. The display device of claim 11, wherein the shift register is formed on the display panel.

13. The display device of claim 11, wherein the gate control signals are transmitted through wires formed on the display panel.

14. The display device of claim 11, wherein the first clock signal and the second clock signal have opposite phases.

15. The display device of claim 11, wherein the transmission signal is a carry signal.
